(19) United States
(12) Patent Application Publication
(10) Pub. No.: US 2022/0365355 A1
(43) Pub. Date: Nov. 17, 2022

(54) HEAD-MOUNTED ELECTRONIC DEVICE

(71) Applicant: PEGATRON CORPORATION, TAIPEI CITY (TW)

(72) Inventor: Jhe Syu Li, Taipei City (TW)

(73) Assignee: PEGATRON CORPORATION, TAIPEI CITY (TW)

(21) Appl. No.: 17/738,997

(22) Filed: May 6, 2022

(30) Foreign Application Priority Data
May 12, 2021 (TW) 110205356

(51) Int. Cl. G02B 27/01

(52) U.S. Cl. CPC G02B 27/0176; G02B 2027/0192

(57) ABSTRACT

A head-mounted electronic device including a body, a circuit board, and a fan is provided. The body includes a first cover, a second cover, and an annular side wall. The annular side wall is encircled to form two opposite openings, and the first cover and the second cover are assembled on the openings. The first cover has a main air outlet and a pair of first air inlets. The second cover has a pair of second air inlets. The circuit board is disposed in the body and is located between the first cover and the second cover. The fan is disposed on the circuit board and is located in the body. An air intake of the fan faces the first cover. The fan draws air from the pair of first air inlets and the pair of second air inlets, and blows the air out of the main air outlet.

### CROSS-REFERENCE TO RELATED APPLICATION

This application claims the priority benefit of Taiwan application serial no. 110205356, filed on May 12, 2021. The entirety of the above-mentioned patent application is hereby incorporated by reference herein and made a part of this specification.

### BACKGROUND

### Technology Field

The disclosure relates to an electronic device, and particularly, to a head-mounted electronic device.

### Description of Related Art

Head-mounted electronic devices, such as virtual reality (VR) devices (hereinafter referred to as VR devices), use computer technology to create a highly realistic 3D virtual world, allowing users to immerse themselves in the environment and have an experience as if in the real world.

The heat dissipation module of a current VR device works as follows: the main heating element of the heat pipe contact system, such as a central processing unit (CPU) or a graphics processing unit (GPU), introduces the heat from the heating area to the cooling area, then the cooling area is directly cooled by a fan, and finally the heat is discharged out of the system, in which the centrifugal fan used is usually single-suction.

A single suction centrifugal fan can only attract cold air from one side. To increase the air convection inside the system to improve the heat dissipation effect, a complex flow channel design is required to attain the purpose.

### SUMMARY

The disclosure provides a head-mounted electronic device with a good heat dissipation effect.

A head-mounted electronic device of the disclosure includes a body, a circuit board, and a fan. The body includes a first cover, a second cover, and an annular side wall. The annular side wall is encircled to form two opposite openings, the first cover and the second cover are assembled on the openings, the first cover has a main air outlet and a pair of first air inlets, and the second cover has a pair of second air inlets. The circuit board is disposed in the body and located between the first cover and the second cover. The fan is disposed on the circuit board and located in the body. An air intake of the fan faces the first cover to draw air from the first air inlets and the second air inlets and blow the air out of the main air outlet.

In an embodiment of the disclosure, the first air inlets are disposed at a junction of the first cover and the annular side wall.

In an embodiment of the disclosure, the first air inlets are assembly gaps between the first cover and the annular side wall.

In an embodiment of the disclosure, the first air inlets are disposed on the first cover.

In an embodiment of the disclosure, the first air inlets are located on two sides of the main air outlet and are correspondingly disposed.

In an embodiment of the disclosure, the second air inlets are located on two sides of the main air outlet and are correspondingly disposed.

In an embodiment of the disclosure, the circuit board has a first surface and a second surface, the first surface faces the first cover, the second surface faces the second cover, the air from the first air inlets flows toward the first surface, and the air from the second air inlets flows toward the second surface.

In an embodiment of the disclosure, the head-mounted electronic device further includes a heat source disposed on the circuit board and located beside the fan.

In an embodiment of the disclosure, the head-mounted electronic device further includes a heat pipe connected between the fan and the heat source.

In an embodiment of the disclosure, the fan is a double suction fan.

In an embodiment of the disclosure, the circuit board has an opening, and the fan is disposed in correspondence with the opening.

In summary, in the head-mounted electronic device of the disclosure, cool air is supplied to the fan from both the upper side and the lower side of the circuit board. Therefore, compared with the conventional head-mounted electronic device, the head-mounted electronic device of the disclosure has more air inlet paths, and the air convection effect inside the head-mounted electronic device is further enhanced.

### BRIEF DESCRIPTION OF THE DRAWINGS

FIG. 1 is a three-dimensional schematic view of a head-mounted electronic device according to the disclosure.

FIG. 2 is a perspective view of the front side of the head-mounted electronic device in FIG. 1.

FIG. 3 is a perspective view of the rear side of the head-mounted electronic device in FIG. 1.

FIG. 4 is a schematic view illustrating where a first air inlet is disposed according to another embodiment.

FIG. 5 is a schematic view of a side of the head-mounted electronic device of FIG. 1.

FIG. 6 is a schematic view of the air flow at the front side of the head-mounted electronic device.

FIG. 7 is a schematic view of the air flow at the rear side of the head-mounted electronic device.

### DESCRIPTION OF THE EMBODIMENTS

The descriptions of directional terms, such as front, back, left, right, up, down, etc. in this specification are only intended to illustrate, rather than limit, the disclosure. When the object used as the reference for the description is replaced, the description of the directional terms will also be different.

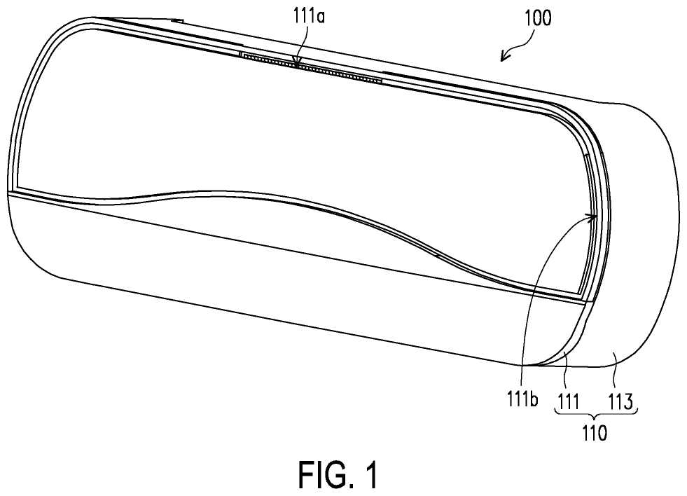

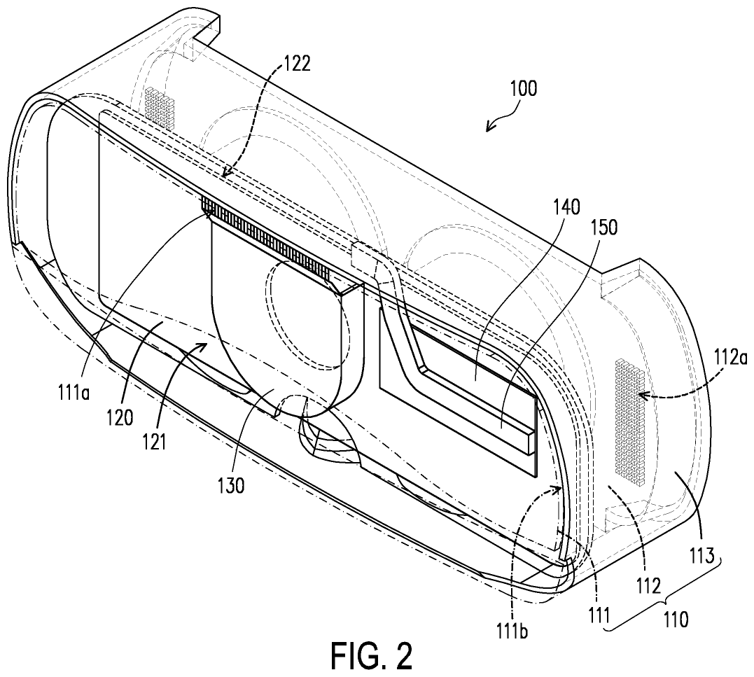

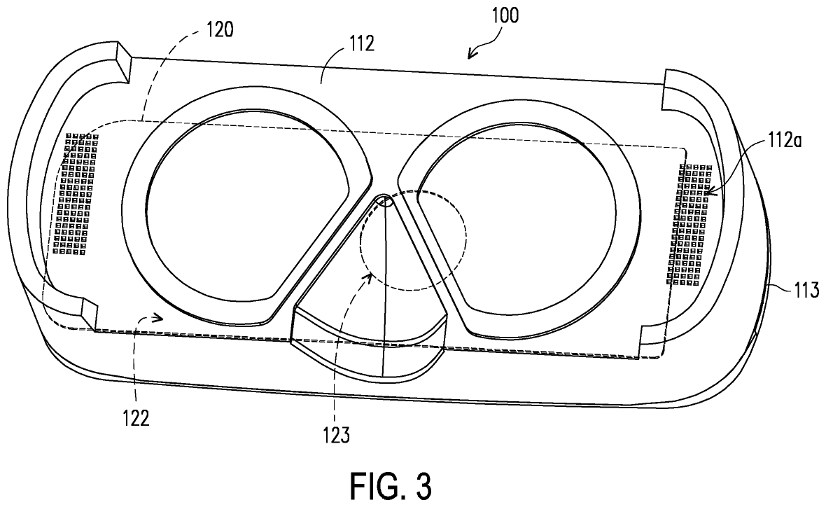

FIG. 1 is a three-dimensional schematic view of a head-mounted electronic device according to the disclosure, FIG. 2 is a perspective view of the front side of the head-mounted electronic device in FIG. 1, and FIG. 3 is a perspective view of the rear side of the head-mounted electronic device in FIG. 1.

Referring to FIG. 1, FIG. 2, and FIG. 3 altogether, a head-mounted electronic device 100 of the disclosure is a virtual reality device, which includes a body 110, a circuit board 120, and a fan 130.

The body 110 includes a first cover 111, a second cover 112, and an annular side wall 113. The annular side wall 113 is encircled to form two opposite openings, and the first cover 111 and the second cover 112 are assembled on the openings. Moreover, the first cover 111 has a main air outlet 111a and a pair of first air inlets 111b, and the second cover 112 has a pair of second air inlets 112a.

Specifically, the first cover 111 is disposed at the front opening (not shown) of the annular side wall 113, and the second cover 112 is disposed at the rear opening (not shown) of the annular side wall 113. To differentiate the front side from the rear side of the annular side wall 113, the side relatively close to or attached to the user is the rear side, and the side relatively far away from the user is the front side when the user wears the head-mounted electronic device 100. That is, when the user wears the head-mounted electronic device 100, the second cover 112 is relatively close to the user and the first cover 111 is relatively far away from the user.

The circuit board 120 is disposed in the body 110 and located between the first cover 111 and the second cover 112.

The fan 130 is disposed on the circuit board 120 and located in the body 110, the air intake of the fan 130 faces the first cover 111 to take in the air drawn from the first air inlets 111b and the second air inlet 112a, and the fan 130 blows the air out of the main air outlet 111a. Specifically, the main air outlet 111a is located on the upper side of the annular side wall 113, so the fan 130 blows the air outwards.

Accordingly, compared to the conventional head-mounted electronic device, there is an additional channel for the head-mounted electronic device 100 of the disclosure to take in the air and a favorable heat dissipation effect may be achieved without the complex flow channel design.

Furthermore, in the embodiment, the first air inlets 111b are located on two sides of the main air outlet 111a and are correspondingly disposed, and the second air inlets 112a are also located on the two sides of the main air outlet 111a and are correspondingly disposed. The two sides where the first air inlets 111b and the second air inlets 112a are located at the main air outlet 111a are different from the two sides where the two openings are formed by the encircled annular side wall and the first cover 111 and the second cover 112 are assembled thereon.

Using the annular side wall 113 as a basis, the first cover 111 and the second cover 112 are disposed at the front opening and the rear opening of the annular side wall 113, a first air inlet 111b and a second air inlet 112a are located on the left side of the annular side wall 113, and another first air inlet 111b and another second air inlet 112a are located on the right side of the annular side wall 113.

To be precise, one first air inlet 111b and one second air inlet 112a are disposed on the left side of the main air outlet 111a, and the other first air inlet 111b and the other second air inlet 112a are also disposed on the right side of the main air outlet 111a.

The positions on the side of the main air outlet 111a where the first air inlet 111b and the second air inlet 112a are disposed may correspond to each other or may not correspond to each other, which may be determined according to actual requirements.

In addition, the first air inlets 111b located on different sides may be disposed symmetrically with the main air outlet 111a as the center of symmetry. Alternatively, considering the positions of other components, the first air inlets 111b on different sides may also be disposed asymmetrically, which is designed according to requirements.

Similarly, the second air inlets 112a located on different sides may be disposed either asymmetrically or symmetrically with the main air outlet 111a as the center of symmetry.

The first air inlets 111b of the embodiment are formed at the junctions of the first cover 111 and the annular side wall 113, and the first air inlets 111b may be assembly gaps between the first cover 111 and the annular side wall 113. Because the assembly gaps between the first cover 111 and the annular side wall 113 are used to form the first air inlets 111b, less through holes are made on the first cover 111 and therefore the integrity of the outlook of the first cover 111 is maintained.

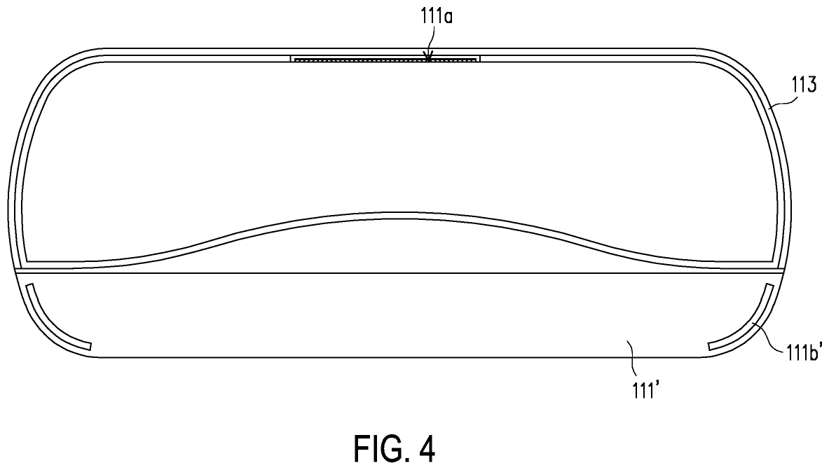

FIG. 4 is a schematic view illustrating where a first air inlet is disposed according to another embodiment. In the embodiment shown in FIG. 4, when it comes to the appearance, a first air inlet 111b′ may be disposed on a first cover 111′.

Accordingly, the positions where the first air inlets 111b and 111b′ are disposed may be adjusted according to practical requirements.

Referring to FIG. 1, FIG. 2, and FIG. 3 again, the circuit board 120 has a first surface 121 and a second surface 122. The first surface 121 faces the first cover 111, and the second surface 122 faces the second cover 112. The first air inlets 111b are disposed on the first cover 111 and the second air inlets 112a are disposed on the second cover 112, so the air at the front side of the body 110 flows from the first air inlets 111b to the first surface 121, and the air at the rear side of the body 110 flows from the second air inlets 112a to the second surface 122.

The fan 130 may be disposed on the first surface 121 or the second surface 122 of the circuit board 120. In the embodiment, the fan 130 is disposed on the first surface 121 of the circuit board 120. The fan 130 in the embodiment is a double suction fan.

The position of the fan 130 corresponds to the nose bridge of the user. This is because when the head-mounted electronic device 100 is worn, the nose bridge of the user can provide greater support.

In addition, the head-mounted electronic device 100 further includes a heat source 140 disposed on the circuit board 120, and the heat source 140 is located beside the fan 130. The heat source 140 may be a central processing unit, a graphics processor, or other electronic components that generate heat. In addition, the head-mounted electronic device 100 may further include a heat pipe 150 connecting the fan 130 with the heat source 140.

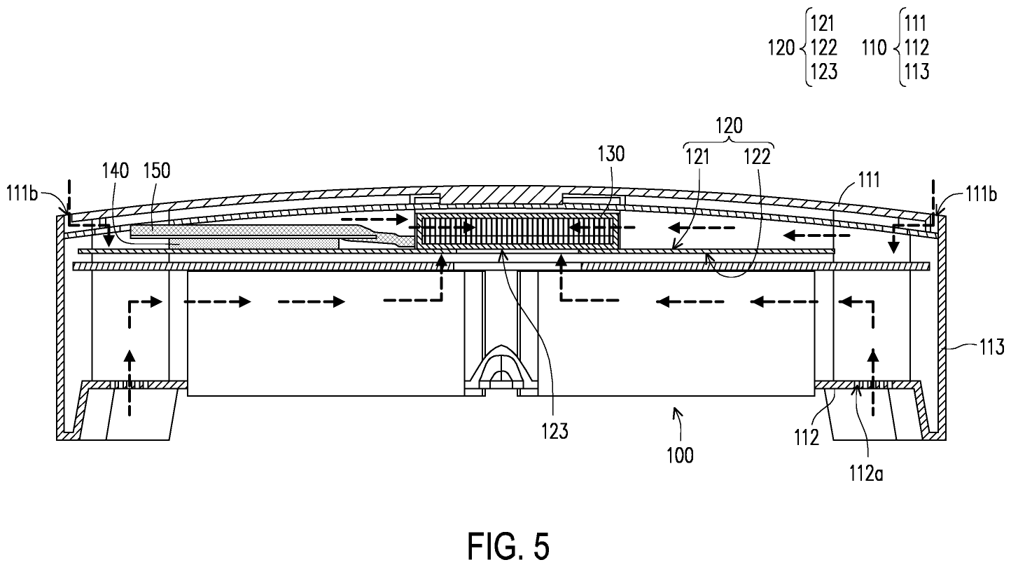

FIG. 5 is a schematic view of a side of the head-mounted electronic device of FIG. 1. FIG. 5 is a simple schematic view clearly illustrating the fan 130, the circuit board 120, and the intake direction of the air. The upper side in FIG. 5 is the front side in FIG. 1, and the lower side in FIG. 5 is the rear side in FIG. 1.

Referring to FIG. 5, to allow the fan 130 to smoothly draw the air from the second air inlets 112a, the circuit board 120 has an opening 123 disposed corresponding to the fan 130. Therefore, the fan 130 can draw the air from both the front side and the rear side.

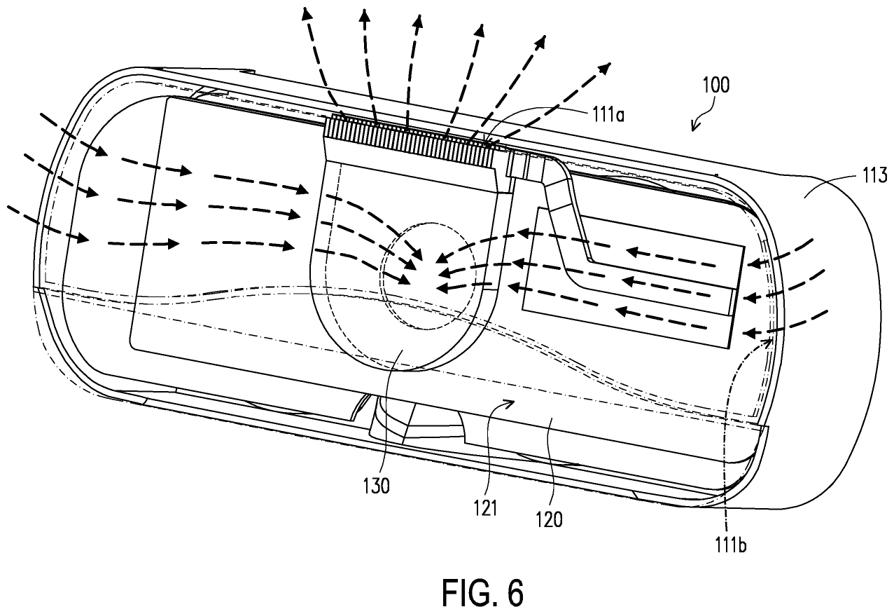

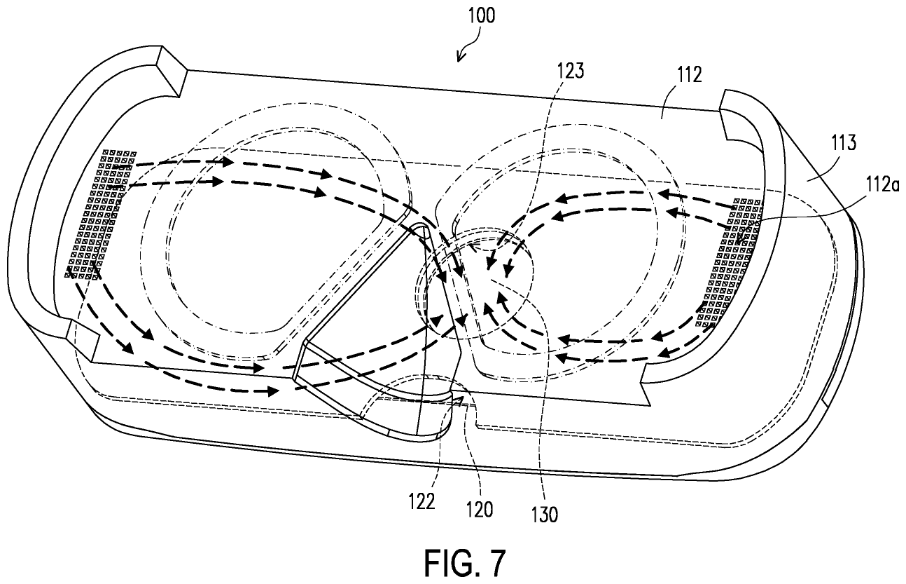

FIG. 6 is a schematic view of the air flow at the front side of the head-mounted electronic device, and FIG. 7 is a schematic view of the air flow at the rear side of the head-mounted electronic device. Refer to FIG. 5, FIG. 6, and FIG. 7 altogether.

When the user wears and uses the head-mounted electronic device 100, the heat source 140, implemented as a central processing unit or a graphics processing unit, receives and processes a large amount of information and therefore generates heat.

The operation of the fan 130 generates forced convection, the cold air outside the head-mounted electronic device 100 enters the body 110 from the first air inlets 111b (shown in FIG. 1) at the front side (i.e., the upper side in FIG. 5), and the cold air flows to the first surface 121 of the circuit board 120 and further into the fan 130. The cold air flowing into the fan 130 is drawn by the flow field formed by the operating fan 130 and is blown out of the main air outlet 111a.

Some of the cold air entering from the first air inlets 111b further passes by the heat source 140 disposed on the circuit board 120, the heat generated by the heat source 140 is taken away when the cold air passes by the heat source 140, and then the air is blown out of the main air outlet 111a.

Meanwhile, the cold air also enters the body 110 from the second air inlets 112a at the rear side (i.e., the lower side in FIG. 5) and flows to the second surface 122 of the circuit board 120 and further into the fan 130. Then, the cold air flowing into the fan 130 is drawn by the flow field formed by the operating fan 130 and is blown out of the main air outlet 111a.

Similarly, some of the cold air entering from the second air inlets 112a further passes by the heat source 140 disposed on the circuit board 120, the heat generated by the heat source 140 is taken away when the cold air passes by the heat source 140, and then the air is blown out of the main air outlet 111a (shown in FIG. 1).

Accordingly, the cold air entering from the first air inlets 111b and the second air inlets 112a takes away the heat generated by the heat source 140 from the upper side and the lower side of the heat source 140, so the favorable heat dissipation effect may be achieved.

In addition, the circuit board 120 divides the body 110 into two sides (the upper side and the lower side as shown in FIG. 5), but the first air inlets 111b and the second air inlets 112a are disposed on respective sides of the circuit board 120, so the air entering from the first air inlets 111b on one side of the circuit board 120 and the second air inlets 112a on the other side of the circuit board 120 flows through most of the area inside the body 110, then is drawn into the fan 130, and subsequently is blown out from the main air outlet 111a. This makes it difficult to accumulate heat inside the head-mounted electronic device 100.

In summary, the head-mounted electronic device of the disclosure allows air to enter from different sides of the circuit board. The cold air flows through a large area of the circuit board, then flows into the fan, and subsequently is blown out from the main air outlet. Compared with the conventional head-mounted electronic device, the head-mounted electronic device of the disclosure has more air inlet paths, and thereby the air convection effect inside the head-mounted electronic device is effectively enhanced.

What is claimed is:

1. A head-mounted electronic device, comprising:
a body comprising a first cover, a second cover, and an annular side wall, wherein the annular side wall is encircled to form two opposite openings, the first cover and the second cover are assembled on the openings, the first cover comprises a main air outlet, and a pair of first air inlets and the second cover comprises a pair of second air inlets;
a circuit board disposed in the body and located between the first cover and the second cover; and
a fan disposed on the circuit board and located in the body, wherein an air intake of the fan faces the first cover to draw air from the first air inlets and the second air inlets and blow the air out of the main air outlet.

2. The head-mounted electronic device according to claim 1, wherein the first air inlets are disposed at a junction of the first cover and the annular side wall.

3. The head-mounted electronic device according to claim 2, wherein the first air inlets are assembly gaps between the first cover and the annular side wall.

4. The head-mounted electronic device according to claim 3, wherein the first air inlets are located on two sides of the main air outlet and are correspondingly disposed.

5. The head-mounted electronic device according to claim 1, wherein the first air inlets are disposed on the first cover.

6. The head-mounted electronic device according to claim 5, wherein the first air inlets are located on two sides of the main air outlet and are correspondingly disposed.

7. The head-mounted electronic device according to claim 1, wherein the second air inlets are located on two sides of the main air outlet and are correspondingly disposed.

8. The head-mounted electronic device according to claim 1, wherein the circuit board comprises a first surface and a second surface, the first surface faces the first cover, the second surface faces the second cover, the air from the first air inlets flows toward the first surface, and the air from the second air inlets flows toward the second surface.

9. The head-mounted electronic device according to claim 1, further comprising a heat source disposed on the circuit board and located beside the fan.

10. The head-mounted electronic device according to claim 9, further comprising a heat pipe connected between the fan and the heat source.

11. The head-mounted electronic device according to claim 1, wherein the fan is a double suction fan.

12. The head-mounted electronic device according to claim 11, wherein the circuit board comprises an opening, and the fan is disposed in correspondence with the opening.
